(19) United States
(12) Patent Application Publication
(10) Pub. No.: US 2016/0269044 A1
(43) Pub. Date: Sep. 15, 2016

(54) CIRCUITS, METHODS, AND MEDIA FOR PROVIDING DELTA-SIGMA MODULATORS

(71) Applicants: Jayanth KUPPAMBATTI, New York, NY (US); Baradwaj VIGRAHAM, San Jose, CA (US); Peter R. KINGET, Summit, NJ (US); THE TRUSTEES OF COLUMBIA UNIVERSITY IN THE CITY OF NEW YORK, New York, NY (US)

(72) Inventors: Jayanth Kuppambatti, New York, NY (US); Baradwaj Vigraham, San Jose, CA (US); Peter R. Kinget, Summit, NJ (US)

(21) Appl. No.: 15/025,111

(22) PCT Filed: Sep. 29, 2014
(86) PCT No.: PCT/US14/58122

§ 371 Date: Mar. 25, 2016

Related U.S. Application Data
(60) Provisional application No. 61/884,015, filed on Sep. 28, 2013.
(60) Provisional application No. 62/008,792, filed on Jun. 6, 2014.

(51) Int. Cl. H03M 3/00

(52) U.S. Cl. CPC H03M 3/464; H03M 3/388

(57) ABSTRACT

Circuits, methods, and media for providing calibrated delta-sigma modulators are provided. In some embodiments, circuits for a delta-sigma modulator are provided, the circuits comprising: an analog-to-digital converter that produces an output having multiple bits; a digital-to-analog converter having an input having multiple bits; a switch coupled between the output the input that can be used to configure connections between the bits of the output and the bits of the input; a hardware processor that: for multiple iterations, sets a configuration of the switch, samples the bits of the output to produce sample values for each bit of the bits of the output, and calculates an average of the sample values for each of the bits of the output values; computes weights for each of the bits of the output values; and calculates weighted output values for every value of the outputs.

### CROSS REFERENCE TO RELATED APPLICATION

This application claims the benefit of U.S. Provisional Patent Application No. 61/884,015, filed Sep. 28, 2013, and U.S. Provisional Patent Application No. 62/008,792, filed Jun. 6, 2014, each of which is hereby incorporated by reference herein in its entirety.

### STATEMENT REGARDING FEDERALLY SPONSORED RESEARCH AND DEVELOPMENT

This invention was made with government support under contract CCF-0964497 awarded by the National Science Foundation, contract PHY-1067934 awarded by the National Science Foundation, and award 1309721 granted by the National Science Foundation. The government has certain rights in the invention.

### TECHNICAL FIELD

The disclosed subject matter relates to circuits, methods, and media for providing delta-sigma modulators.

### BACKGROUND

The use of delta-sigma modulator circuits for analog-to-digital conversion is increasing in popularity due to various properties of the circuits like inherent anti-aliasing and resistive input drive.

An example 100 of a prior-art, multi-bit continuous-time delta sigma modulator (CTDSM) is illustrated in FIG. 1. As shown, CTDSM 100 includes a subtracter 102, a filter 104, an N-level analog-to-digital converter (ADC) 106, and an N-level digital-to-analog converter (DAC) 108.

During operation of circuit 100, a feedback signal V_{fb} is subtracted from an input signal Vᵢₙ by subtracter 102 to produce a difference signal. This difference signal is then provided to filter 104, which filters the difference signal to produce a filtered signal. ADC 106 then converts the analog filtered signal to a digital N-bit, thermometer-coded output, D<N-1:0>. The thermometer-coded output is then converted back to the analog feedback signal V_{fb} and provided to subtracter 102 by DAC 108.

When a DAC (such as DAC 108) in a delta sigma modulator (such as CTDSM 100) is not matched to its ADC (such as ADC 106) (i.e., a mismatch between the unit elements of the DAC and the unit elements of the ADC), non-linearities and errors can be produced in the modulator's output.

Accordingly, new mechanisms for providing delta-sigma modulators are desirable.

### SUMMARY

Circuits, methods, and media for providing delta-sigma modulators are provided. In some embodiments, circuits for a delta-sigma modulator are provided, the circuits comprising: an analog-to-digital converter that produces an output having multiple bits; a digital-to-analog converter having an input having multiple bits; a switch coupled between the output the input that can be used to configure connections between the bits of the output and the bits of the input; a hardware processor that: for multiple iterations, sets a configuration of the switch, samples the bits of the output to produce sample values for each bit of the bits of the output, and calculates an average of the sample values for each of the bits of the output values; computes weights for each of the bits of the output values; and calculates weighted output values for every value of the outputs.

In some embodiments, methods for providing a delta-sigma modulator are provided, the methods comprising: performing an analog-to-digital conversion to produce an output having multiple bits; performing a digital-to-analog conversion to produce an input having multiple bits; using a hardware processor to: for multiple iterations, set a configuration of between the bits of the output and the bits of the input, sample the bits of the output to produce sample values for each bit of the bits of the output, and calculate an average of the sample values for each of the bits of the output values; compute weights for each of the bits of the output values; and calculate weighted output values for every value of the outputs.

In some embodiments, non-transitory computer readable media containing computer executable instructions that, when executed by a processor, cause the processor to perform a method for providing a delta-sigma modulator are provided, the method comprising: for multiple iterations, setting a configuration of between bits of an output of an analog-to-digital conversion and bits of input of a digital-to-analog conversion, sampling the bits of the output to produce sample values for each bit of the bits of the output, and calculating an average of the sample values for each of the bits of the output values; computing weights for each of the bits of the output values; and calculating weighted output values for every value of the outputs.

### BRIEF DESCRIPTION OF THE DRAWINGS

FIG. 1 is a circuit diagram showing a prior-art, multi-bit Continuous Time Delta Sigma Modulator (CTDSM).

FIG. 2 is a circuit diagram showing a calibrated multi-bit CTDSM in accordance with some embodiments of the disclosed subject matter.

FIG. 3 is a flow diagram illustrating an example of a process for performing calibration in accordance with some embodiments of the disclosed subject matter.

FIG. 4A is a circuit diagram showing Analog-to-Digital Converter (ADC) and Digital-to-Analog Converter (DAC) connections during an iteration of a calibration process in accordance with some embodiments of the disclosed subject matter.

FIG. 4B is a circuit diagram showing the ADC and DAC connections during another iteration of a calibration process in accordance with some embodiments of the disclosed subject matter.

### DETAILED DESCRIPTION

Circuits, methods, and media for providing delta-sigma modulators are provided. In accordance with some embodiments, the delta-sigma modulators can be continuous-time delta sigma modulators (CTDSMs), though the delta-sigma modulators can be discrete time delta sigma modulators in some embodiments. For the purposes of clarity, calibration of delta-sigma modulators is described herein in connection with CTDSMs. However, it should be apparent to one of skill in the art that the mechanisms described herein can be used with non-continuous-time delta sigma modulators in some embodiments.

As described further below, in accordance with some embodiments, a calibration mechanism is provided that, under the control of a control circuit, populates a look-up table (LUT) at the output of the delta-sigma modulator with calibrated output values for every possible output value of the modulator's ADC. This LUT is constructed by performing a number of calibration iterations, during each of which: the input to the modulator is held at a constant DC value (which can be a fixed value or a constant DC value with a varying AC component); the connections between the output of the modulator's ADC and the modulator's DAC are switched (e.g., using a circular shifter) from the other iterations; and an average of a number of samples of each bit of the ADC output is calculated. The averages are then used to solve for weights for each bit of the ADC output. Finally, the LUT is populated by applying the weights to each possible input to the LUT and storing the resulting values in the LUT.

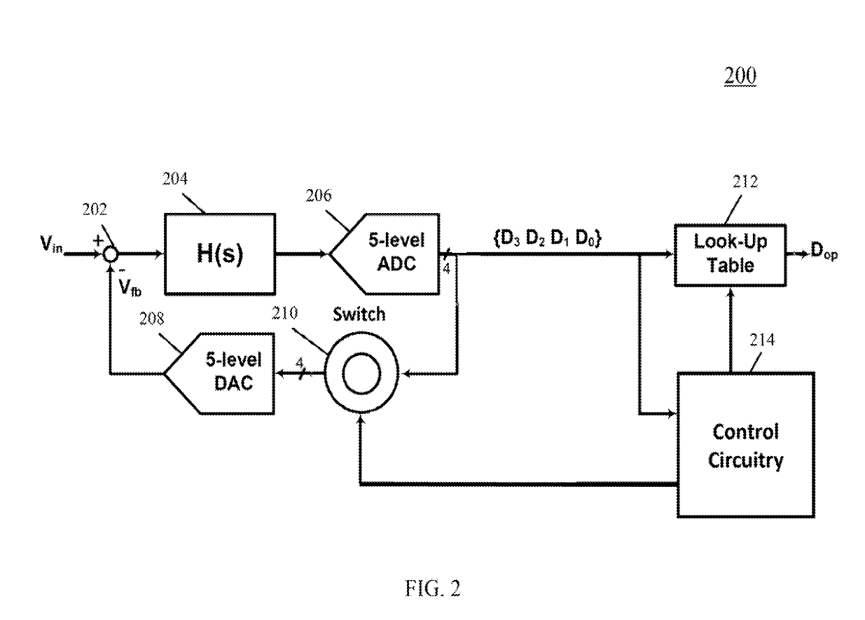

Turning to FIG. 2, an example 200 of a calibrated multi-bit CTDSM in accordance with some embodiments of the disclosed subject matter is shown. As illustrated, CTDSM 200 includes subtracter 202, filter 204, ADC 206, and DAC 208, which can be similar to subtracter 202, filter 204, ADC 206, and DAC 208 in some embodiments. CTDSM 200 can also include a switch 210 (e.g., which can be a circular shifter as shown in FIG. 2), a look-up table (LUT) 212, and control circuitry 214 that can be used to calibrate circuit 200.

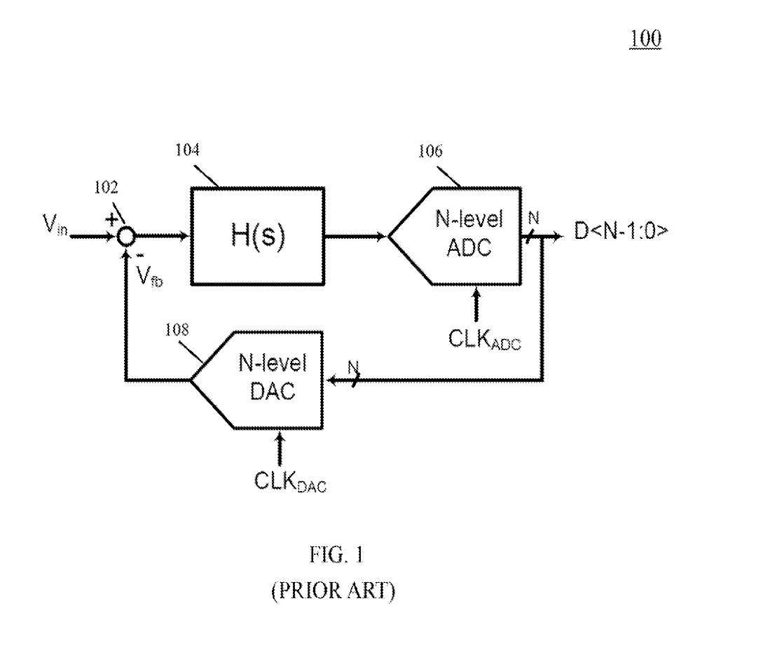

Like what is described above for FIG. 1, during normal operation of circuit 200, a feedback signal V_{fb} is subtracted from an input signal Vᵢₙ by subtracter 202 to produce a difference signal. This difference signal is then provided to filter 204, which filters the difference signal to produce a filtered signal. ADC 206 then converts the analog filtered signal to a digital N-bit, thermometer-coded output, D<N-1:0>. The thermometer-coded output is then converted back to the analog feedback signal V_{fb} and provided to subtracter 202 by DAC 208 (which (unlike in circuit 100 of FIG. 1) receives the output from ADC 206 via switch 210 (which can be in any state because the shifting does not impact the value provided to the ADC due to the thermometer coding. Also, unlike circuit 100 of FIG. 1, the output of circuit 200 is provided by LUT 212 which provides a calibrated output Dₒₚ based on the output of ADC 206 and weighted values that have been populated into it.

A calibration process can be used in connection with switch 210, LUT 212, and control circuitry 214 of FIG. 2 to provide calibrated output Dₒₚ. Any suitable calibration process can be used in some embodiments.

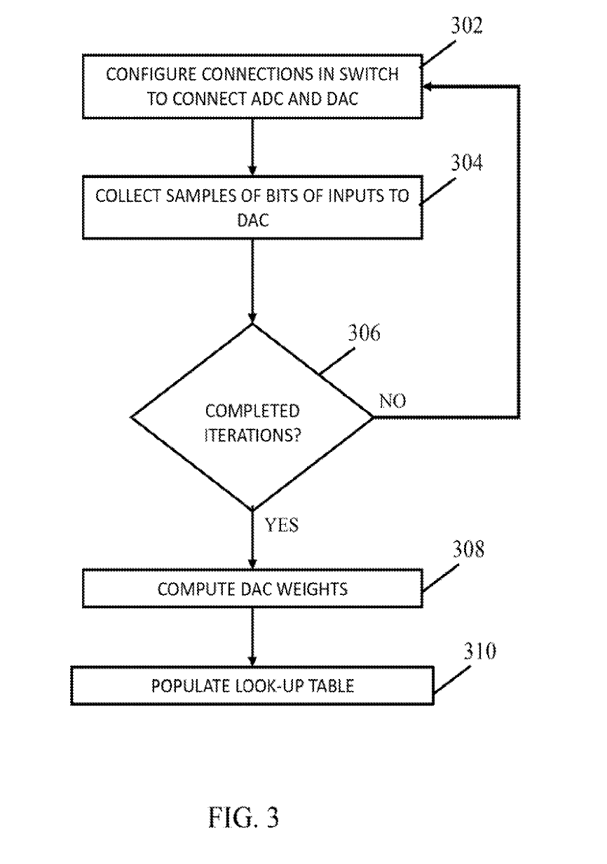

For example, calibration process 300 of FIG. 3 can be used in some embodiments. This calibration process can be executed in control circuitry 214 in some embodiments.

The calibration process can perform a number of calibration iterations. Any suitable number of iterations can be performed in some embodiments. For example, with an N-level ADC (such as five-level ADC 206 of FIG. 2), N−1 iterations (or four iterations for the circuit of FIG. 2) can be performed.

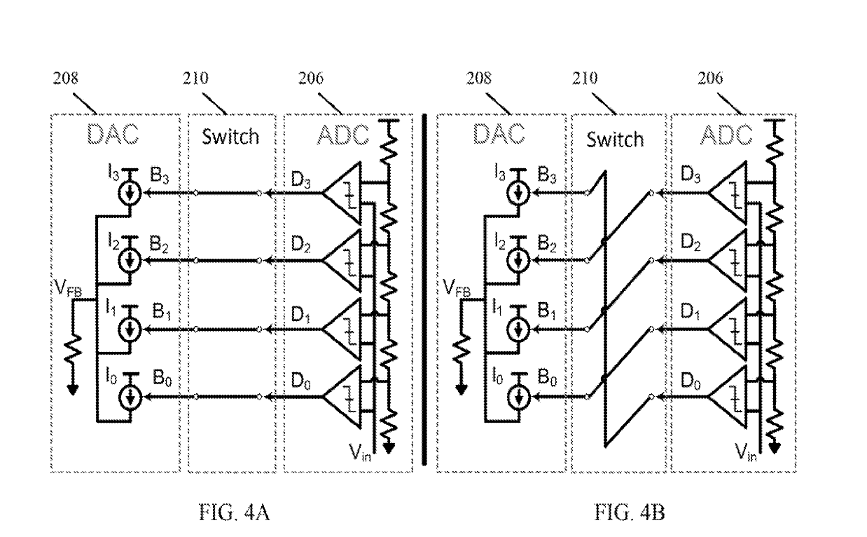

As shown in FIG. 3, after calibration process 300 has begun, the process can begin a first iteration (j=1) by configuring switch 210 to connect the outputs of ADC 206 to the inputs of DAC 208 at 302. The switch can be configured in any suitable manner and to have any suitable initial connection arrangement. For example as shown in FIG. 4A, during the first iteration, the switch can be configured to connect Dᵢ to Bᵢ, where i=0, . . . , 3 are the bit numbers of the input bits (Bᵢ) of the DAC and the output bits (Dᵢ) of the ADC. More particularly, for example, as shown in FIG. 4A, D₃ can be connected to B₃, D₂ can be connected to B₂, D₁ can be connected to B₁, and D₀ can be connected to B₀. A table showing an example of the connections between the ADC outputs and the DAC inputs for four iterations in a five-level-ADC, four-iteration embodiment is shown below:

| | |
|---|---|
| ADC | DAC INPUTS |

| OUTPUTS | j = 1 | j = 2 | j = 3 | j = 4 |
|---|---|---|---|---|
| D₃ | B₃ | B₂ | B1 | B₀ |
| D₂ | B₂ | B1 | B₀ | B₃ |
| D₁ | B1 | B₀ | B₃ | B₂ |
| D₀ | B₀ | B₃ | B₂ | B1 |

Next, process 300 can collect and average samples of each of the input bits to DAC 208 as output by the output bits of ADC 206, and store these averages, at 304. As described above, these samples can be collected while the input signal Vᵢₙ has a constant DC value—i.e., either has a fixed value or has a constant DC value with a varying AC value. Any suitable number of samples can be collected in some embodiments. For example, in some embodiments, for an n-bit delta-sigma modulator, at least 2ⁿ+1 samples (or 2¹⁵+1 samples for a n=15-bit delta-sigma modulator) can be collected. For each of the iterations j, the average values of the DAC input bits Bᵢ over n samples can be represented by:

$${\overline{B}}_{ij} = \frac{1}{n} {\sum }_{k = 1}^{n} {B}_{ij} [ k ]$$

These samples can be collected from the outputs of the ADC or from the inputs to the DAC in some embodiments. These averages can be stored in any suitable manner in any suitable location, such as memory part of or coupled to control circuitry 214.

Then, at 306, process 300 can determine whether a certain number of iterations have been performed. As described above, in some embodiments, N−1 iterations can be performed for a delta-sigma modulator having an N-level ADC. Thus, for five-level ADC 206 of FIG. 2, the process can perform four iterations. If it is determined at 306 that the certain number of iterations have not been performed, the process can increment the iteration number (i.e., set j=2 for the second iteration) and loop back to 302 to re-configure switch 210 for the next iteration (e.g., as illustrated in the table above). For example, the switch can be configured as shown in FIG. 4B for the second iteration. Otherwise, the process can continue to 308.

At 308, process 300 can compute weights Iᵢ for each bit i of the outputs of ADC 206 to be used to populate LUT 212. These weights can be computed in any suitable manner. For example, in some embodiments, these weights can be computed one way when the input signal Vᵢₙ can be determined and when Vᵢₙ is not equal to zero, and these weights can be computed in another way when it can be determined that the DC component of Vᵢₙ is fixed (whether the exact value of Vᵢₙ is known or not), but that the AC component of Vᵢₙ is varying or may be varying, or when Vᵢₙ is equal to zero.

When input signal Vᵢₙ can be determined and Vᵢₙ is not equal to zero, the weights Iᵢ can be determined, in some embodiments, by solving a set of linear equations like what follows (which is shown, for purposes of illustration only, for a four bit output and four iterations):

$$[ \begin{matrix}{V}_{in} \\ {V}_{in} \\ {V}_{in} \\ {V}_{in}\end{matrix} ] = [ \begin{matrix}{\overline{B}}_{31} & {\overline{B}}_{21} & {\overline{B}}_{11} & {\overline{B}}_{01} \\ {\overline{B}}_{32} & {\overline{B}}_{22} & {\overline{B}}_{12} & {\overline{B}}_{02} \\ {\overline{B}}_{33} & {\overline{B}}_{23} & {\overline{B}}_{13} & {\overline{B}}_{03} \\ {\overline{B}}_{34} & {\overline{B}}_{24} & {\overline{B}}_{14} & {\overline{B}}_{04}\end{matrix} ] [ \begin{matrix}{I}_{3} \\ {I}_{2} \\ {I}_{1} \\ {I}_{0}\end{matrix} ] .$$

When it can be determined that the DC component of Vᵢₙ is fixed, but that the AC component of Vᵢₙ is varying or may be varying, or when Vᵢₙ is equal to zero, the weights Iᵢ can be determined first by setting any one of the weights (e.g., I₀) to any suitable scalar value (e.g., such as 1) and then solving for the remaining weights Iᵢ using the following set of linear equations (which, again, is shown, for purposes of illustration only, for a four bit output and four iterations):

$$- [ \begin{matrix}{\overline{B}}_{31} - {\overline{B}}_{32} \\ {\overline{B}}_{32} - {\overline{B}}_{33} \\ {\overline{B}}_{33} - {\overline{B}}_{34}\end{matrix} ] = [ \begin{matrix}{\overline{B}}_{21} - {\overline{B}}_{22} & {\overline{B}}_{11} - {\overline{B}}_{12} & {\overline{B}}_{01} - {\overline{B}}_{02} \\ {\overline{B}}_{22} - {\overline{B}}_{23} & {\overline{B}}_{12} - {\overline{B}}_{13} & {\overline{B}}_{02} - {\overline{B}}_{03} \\ {\overline{B}}_{23} - {\overline{B}}_{24} & {\overline{B}}_{13} - {\overline{B}}_{14} & {\overline{B}}_{03} - {\overline{B}}_{04}\end{matrix} ] [ \begin{matrix}{I}_{3} \\ {I}_{2} \\ {I}_{1}\end{matrix} ]$$

The above set of linear equations can be obtained by setting I₀=1 and re-arranging the following general formula:

$$[ \begin{matrix}0 \\ 0 \\ 0\end{matrix} ] = [ \begin{matrix}{\overline{B}}_{31} - {\overline{B}}_{32} \\ {\overline{B}}_{32} - {\overline{B}}_{33} \\ {\overline{B}}_{33} - {\overline{B}}_{34}\end{matrix} \begin{matrix}{\overline{B}}_{21} - {\overline{B}}_{22} & {\overline{B}}_{11} - {\overline{B}}_{12} & {\overline{B}}_{01} - {\overline{B}}_{02} \\ {\overline{B}}_{22} - {\overline{B}}_{23} & {\overline{B}}_{12} - {\overline{B}}_{13} & {\overline{B}}_{02} - {\overline{B}}_{03} \\ {\overline{B}}_{23} - {\overline{B}}_{24} & {\overline{B}}_{13} - {\overline{B}}_{14} & {\overline{B}}_{03} - {\overline{B}}_{04}\end{matrix} ] [ \begin{matrix}{I}_{3} \\ {I}_{2} \\ {I}_{1} \\ {I}_{0}\end{matrix} ]$$

The above sets of linear equations are provided herein only for purposes of illustration and these equations can be modified to cover embodiments with ADCs with different numbers of output bits and/or calibration processes with different numbers of iterations.

Finally, at 310, process 300 can use the weights Iᵢ to populate LUT 212. This can be accomplished, for example, by, for each possible output value of ADC 206, multiplying the value of each bit (D₃, D₂, D₁, or D₀) of that output value by the corresponding weight (I₃, I₂, I₁, or I₀), summing the resulting products to a resulting sum, and storing the resulting sum (made up of D₃*I₃+D₂*I₂+D₁*I₁+D₀*I₀ in the example) in the LUT indexed by the output value. Because the weights may be non-integer values, the resulting sums stored may be real values. For example, with values of +1, −1, +1, and +1 for D₃, D₂, D₁, and D₀, respectively, and values of 1.1, 1.1, 1.2, and 1 for I₃, I₂, I₁, and I₀, respectively, resulting products of +1.1, −1.1, +1.2, and +1 may be calculated, and a resulting sum of +2.2 stored in the LUT for ADC outputs +1, −1, +1, and +1 for D₃, D₂, D₁, and D₀, respectively. In this way, when a particular ADC output value is presented at the input to the LUT, the output of the LUT will provide that value as modified, at the bit level, by weights Iᵢ.

Referring back to FIG. 2, subtracter 202 can be any suitable component(s) or connection for subtracting feedback signal V_{fb} from an input signal Vᵢₙ, in some embodiments. For example, in some embodiments, subtracter 202 can be a differential amplifier for subtracting voltage signals, a circuit connection for subtracting current signals, etc.

Filter 204 can be any suitable component(s) for filtering the difference signal output by subtracter 202. For example, in some embodiments, filter 204 can be a loop filter.

ADC 206 can be any suitable analog-to-digital converter that has the same number of bits as DAC 208. For example, in some embodiments, ADC 206 can be a five-level ADC that has a four-bit thermometer coded output. Any suitable type of ADC, any suitable number of levels can be used in ADC 206, and any suitable coding can be used.

DAC 208 can be any suitable digital-to-analog converter that has the same number of bits as ADC 206. For example, in some embodiments, DAC 208 can be a five-level DAC that has a four-bit thermometer coded input. Any suitable type of DAC can be used, any suitable number of levels can be used in DAC 208. As another example, although a current DAC is illustrated in FIGS. 4A and 4B, any suitable DAC type and any suitable DAC pulse shape can be used, such as a non-return-to-zero DAC, a return-to-zero DAC, a switched-capacitor DAC, a resistive DAC, etc.

Switch 210 can be any switch for configuring the connections between the outputs of ADC 206 and the inputs of DAC 208. For example, in some embodiments, switch 210 can be implemented as a (N−1)×(N−1) switch matrix which implements a circular shifter. In some embodiments, the order of changing the connections between the bits of the ADC and the bits of the DAC can occur in any order that connects each ADC bit to each DAC bit, and need not be done in the order of a circular shifter as described herein.

LUT 212 can be any device suitable for use as a look-up table. For example, in some embodiments, LUT 212 can be implemented using a flash memory device (or any other suitable alterable memory device (such as an EEPROM, RAM, etc.) having the same number of data input bits as ADC 206 has output bits.

Control circuitry 214 can be any suitable circuitry or combination of circuitry for controlling switch, sampling the ADC output values, calculating the averages and weights, populating the LUT, and/or performing any other suitable functions as described herein. For example control circuitry 214 can include a hardware processor and memory, dedicated logic circuitry, a computer, and/or any other suitable components.

In some embodiments, any suitable computer readable media can be used for storing instructions for performing the processes described herein. Such computer readable media can be part of or coupled to control circuitry 214. For example, in some embodiments, computer readable media can be transitory or non-transitory. For example, non-transitory computer readable media can include media such as magnetic media (such as hard disks, floppy disks, and/or any other suitable media), optical media (such as compact discs, digital video discs, Blu-ray discs, and/or any other suitable optical media), semiconductor media (such as flash memory, electrically programmable read only memory (EPROM), electrically erasable programmable read only memory (EEPROM), and/or any other suitable semiconductor media), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

It should be noted that the above steps of the flow diagram of FIG. 3 can be executed or performed in any order or sequence not limited to the order and sequence shown and described in the figure. Also, some of the above steps of the flow diagram of FIG. 3 can be executed or performed substantially simultaneously where appropriate or in parallel to reduce latency and processing times. Furthermore, it should be noted that FIG. 3 is provided as an example only. At least some of the steps shown in this figure may be performed in a different order than represented, performed concurrently, or altogether omitted.

The provision of the examples described herein (as well as clauses phrased as “such as,” “e.g.,” “including,” and the like) should not be interpreted as limiting the claimed subject matter to the specific examples; rather, the examples are intended to illustrate only some of many possible aspects.

Although the invention has been described and illustrated in the foregoing illustrative embodiments, it is understood that the present disclosure has been made only by way of example, and the numerous changes in the details of implementation of the invention can be made without departing from the spirit and scope of the invention, which is only limited by the claims which follow. Features of the disclosed embodiments can be combined and rearranged in various ways.

What is claimed is:

1. A circuit for a delta-sigma modulator, comprising:
an analog-to-digital converter that produces an output having multiple bits;
a digital-to-analog converter having an input having multiple bits;
a switch coupled between the output and the input that can be used to configure connections between the bits of the output and the bits of the input;
a hardware processor that:
for multiple iterations, sets a configuration of the switch, samples the bits of the output to produce sample values for each bit of the bits of the output, and calculates an average of the sample values for each of the bits of the output values;
computes weights for each of the bits of the output values; and
calculates weighted output values for every value of the outputs.

2. The circuit of claim 1, wherein the output is thermometer coded.

3. The circuit of claim 1, wherein the input is thermometer coded.

4. The circuit of claim 1, wherein the digital-to-analog converter is a current digital-to-analog converter.

5. The circuit of claim 1, wherein the switch is a circular shifter.

6. The circuit of claim 1, wherein the hardware processor sets the configuration of the switch over the multiple iterations in an order other than an order used by a circular shifter.

7. The circuit of claim 1, further comprising a memory device coupled to the output, wherein the hardware processor also populates the weighted output values in the memory device.

8. The circuit of claim 1, wherein for n output bits of the analog-to-digital converter represented by Dₙ₋₁, . . . , D₀, n weights represented by Iₙ₋₁, . . . , I₀ are computed, and wherein the weighted output values are equal to Σᵢ₌₀ⁿ⁻¹Dᵢ*Iᵢ.

9. A method for providing a delta-sigma modulator, comprising:
performing an analog-to-digital conversion to produce an output having multiple bits;
performing a digital-to-analog conversion to produce an input having multiple bits;
using a hardware processor to:
for multiple iterations, set a configuration of between the bits of the output and the bits of the input, sample the bits of the output to produce sample values for each bit of the bits of the output, and calculate an average of the sample values for each of the bits of the output values;
compute weights for each of the bits of the output values; and
calculate weighted output values for every value of the outputs.

10. The method of claim 9, wherein the output is thermometer coded.

11. The method of claim 9, wherein the input is thermometer coded.

12. The method of claim 9, wherein the digital-to-analog conversion is performed using a current digital-to-analog converter.

13. The method of claim 9, wherein the hardware processor sets the configuration of between the bits of the output and the bits of the input using a circular shifter.

14. The method of claim 9, wherein the hardware processor sets the configuration of between the bits of the output and the bits of the input over the multiple iterations in an order other than an order used by a circular shifter.

15. The method of claim 9, wherein the hardware processor also populates the weighted output values in a memory device.

16. The method of claim 9, wherein for n output bits of the analog-to-digital conversion represented by Dₙ₋₁, . . . , D₀, n weights represented by Iₙ₋₁, . . . , I₀ are computed, and wherein the weighted output values are equal to Σᵢ₌₀ⁿ⁻¹Dᵢ*Iᵢ.

17. A non-transitory computer readable medium containing computer executable instructions that, when executed by a processor, cause the processor to perform a method for providing a delta-sigma modulator, the method comprising:
for multiple iterations, setting a configuration of between bits of an output of an analog-to-digital conversion and bits of input of a digital-to-analog conversion, sampling the bits of the output to produce sample values for each bit of the bits of the output, and calculating an average of the sample values for each of the bits of the output values;
computing weights for each of the bits of the output values; and
calculating weighted output values for every value of the outputs.
